(19) United States
(12) Patent Application Publication
(10) Pub. No.: US 2022/0028724 A1
(43) Pub. Date: Jan. 27, 2022

(54) ADAPTER PLATE, MASS TRANSFER METHOD, AND MICRO-LED DISPLAY

(71) Applicant: CHONGQING KONKA PHOTOELECTRIC TECHNOLOGY RESEARCH INSTITUTE CO., LTD., Chongqing (CN)

(72) Inventor: Feng ZHAI, Chongqing (CN)

(21) Appl. No.: 17/395,146

(22) Filed: Aug. 5, 2021

Related U.S. Application Data
(63) Continuation of application No. PCT/CN2020/104886, filed on Jul. 27, 2020.

(51) Int. Cl. H01L 21/683; H01L 25/075; H01L 33/00; H01L 33/62

(52) U.S. Cl. CPC H01L 21/6835; H01L 25/0753; H01L 33/0093; H01L 2933/0066; H01L 2221/68354; H01L 2221/68368; H01L 33/62

(57) ABSTRACT

An adapter plate is provided. The adapter plate is used in a manufacturing process of a Micro-LED display to realize a mass transfer of LEDs. The adapter plate includes a substrate and a bonding adhesive layer laminated on the substrate and is used to bind and transfer the LEDs, where the bonding adhesive layer is made of organic silicone or acrylic acid. The bonding adhesive layer has a thickness H satisfying: 10 um≤H≤25 um, and has porosity P satisfying: 20%≤P≤40%, to make the bonding adhesive layer have a first adhesive force F1 in an environment at a first temperature T1 and have a second adhesive force F2 in an environment at a second temperature T2 higher than the first temperature T1. The first adhesive force F1 is greater than the second adhesive force F2.

### CROSS-REFERENCE TO RELATED APPLICATION (S)

This application is a continuation of International Application No. PCT/CN2020/104886, filed on Jul. 27, 2020, the disclosure of which is hereby incorporated by reference in its entirety.

### TECHNICAL FIELD

This disclosure relates to the field of display manufacturing technology, and more particularly to an adapter plate used in a mass transfer process, a mass transfer method, and a Micro-LED (light-emitting diode) display manufactured by adopting the mass transfer method.

### BACKGROUND

A Micro-LED (light-emitting diode) display has higher stability, longer life and improved operating temperature. Meanwhile, the Micro-LED display also inherits advantages from a LED, which include low power consumption, high color saturation, high reaction rate, and high contrast ratio. Display brightness of the Micro-LED display is 30 times higher than that of organic light-emitting diode (OLED) and power consumption amount of the Micro-LED display is approximately 10% of that of liquid crystal display (LCD) and 50% of that of OLED. The Micro-LED display has wide prospects of application.

For the current Micro-LED display, multiple LEDs are grown on a growth substrate, and subsequently, the LEDs are removed from the growth substrate, through a temporary substrate, and transferred, through a transfer substrate, to a display back plate of the Micro-LED display for alignment and equipment. In the process from being grown to being fixed on the display back plate, the LEDs need to be transferred twice. To ensure smooth transfer of the LEDs in two transfer processes, retention force on the LEDs needs to be increased step by step in each transfer process, to produce an apparent difference in retention force in each transfer process, for peeling off the LEDs.

However, the increased retention force step by step will make it difficult to peel off the LEDs in the subsequent transfer process, which may cause damage to the LEDs themselves or the display back plate.

### SUMMARY

According to a first aspect, an adapter plate is provided. The adapter plate is used in a manufacturing process of a Micro-LED display to realize the mass transfer of LEDs. The adapter plate includes a substrate and a bonding adhesive layer laminated on the substrate and used to bind and transfer the LEDs, where the bonding adhesive layer is made of organic silicone or acrylic acid. The bonding adhesive layer has a thickness H satisfying: 10 um≤H≤25 um, and has porosity P satisfying: 20%≤P≤40%, to make the bonding adhesive layer have a first adhesive force F1 in an environment at a first temperature T1 and have a second adhesive force F2 in an environment at a second temperature T2 higher than the first temperature T1. The first adhesive force F1 is greater than the second adhesive force F2.

According to a second aspect, a mass transfer method is provided. The mass transfer method is for LED transfer by using the adapter plate of the first aspect and includes the following.

Multiple LEDs are disposed on a first substrate. The adapter plate is connected with the first substrate in the environment at the second temperature T2, to make the bonding adhesive layer attach to at least a portion of the multiple LEDs. The adapter plate is cooled to the environment at the first temperature T1 and the LEDs attached to the adapter plate are transferred for connecting with a second substrate, to make the LEDs attach to the second substrate. The adapter plate is heated to the environment at the second temperature T2 and the LEDs are transferred to the second substrate.

According to a third aspect, a Micro-LED display is provided. The Micro-LED display includes a display back plate and multiple LEDs fixed on the display back plate. The multiple LEDs are fixed on the display back plate by adopting the mass transfer method of the second aspect.

### BRIEF DESCRIPTION OF THE DRAWINGS

This disclosure is best understood from the following detailed description when read in conjunction with the accompanying drawings. Apparently, the accompanying drawings in the following description illustrate some implementations of this disclosure. Those of ordinary skill in the art may also obtain other drawings based on these accompanying drawings without creative efforts.

FIG. 1 is a plan schematic diagram showing a Micro-LED display according to this disclosure.

FIG. 2 is a schematic diagram showing a growing process of a single LED of a Micro-LED display according to this disclosure.

FIG. 3 is a schematic diagram showing a mass transfer process of a Micro-LED display according to this disclosure.

FIG. 4 is a schematic diagram showing a temporary substrate in a mass transfer process of a Micro-LED display according to this disclosure.

FIG. 5 is a schematic diagram showing another operation in a mass transfer process of a Micro-LED display according to this disclosure.

FIG. 6 is a schematic diagram showing a transfer substrate in a mass transfer process of a Micro-LED display according to this disclosure.

FIG. 7 is a schematic diagram showing yet another operation in a mass transfer process of a Micro-LED display according to this disclosure.

FIG. 8 is a schematic diagram showing a display back plate in a mass transfer process of a Micro-LED display according to this disclosure.

FIG. 9 is a schematic diagram showing an adapter plate according to this disclosure.

FIG. 10 is a flow chart showing a mass transfer method according to implementations of this disclosure.

FIG. 11 is a flow chart showing a mass transfer method according to other implementations of this disclosure.

FIG. 12 is a flow chart showing a mass transfer method according to other implementations of this disclosure.

### DETAILED DESCRIPTION

Technical solutions in the implementations of this disclosure will be described clearly and completely hereinafter with reference to the accompanying drawings in the implementations of this disclosure. Apparently, the described implementations are merely some rather than all implementations of this disclosure. All other implementations obtained by those of ordinary skill in the art based on the implementations of this disclosure without creative efforts shall fall within the protection scope of this disclosure.

In addition, the described implementations are the implementations with reference to the accompanying drawings to cite an example of certain implementations which are applicable in this disclosure. Terms of direction are used in this disclosure, such as “up”, “down”, “front”, “back”, “left”, “right”, “inside”, “outside”, “side”, etc. These terms are merely for the reference to the direction of the accompanying drawings. Therefore, the terms of direction are used herein for the purpose of better and more clearly explaining and understanding this disclosure rather than implying or explicitly describing that the referred device or element has to have certain direction or has to be constituted and operated at certain direction. Therefore, the terms of direction cannot be interpreted as limitation to this disclosure.

This disclosure aims to solve deficiencies in the related art and provides an adapter plate with an adjustable adhesive force and for conducting a mass transfer of LEDs. Technical solutions of implementations can be achieved as follows. The adapter plate is used in a manufacturing process of a Micro-LED display to realize the mass transfer of LEDs. The adapter plate includes a substrate and a bonding adhesive layer laminated on the substrate and used to bind and transfer the LEDs, where the bonding adhesive layer is made of organic silicone or acrylic acid. The bonding adhesive layer has a thickness H satisfying: 10 um≤H≤25 um, and has porosity P satisfying: 20%≤P≤40%, to make the bonding adhesive layer have a first adhesive force F1 in an environment at a first temperature T1 and have a second adhesive force F2 in an environment at a second temperature T2 higher than the first temperature T1. The first adhesive force F1 is greater than the second adhesive force F2.

In some implementations, the bonding adhesive layer is made of polydimethylsiloxane diluted with dimethylbenzene. A ratio of the dimethylbenzene to the polydimethylsiloxane is in a range of 2:1˜4:1, which can ensure fluidity of materials when preparing the bonding adhesive layer.

In some implementations, the bonding adhesive layer has an aperture d satisfying: 50 nm≤d≤1000 nm, during which the adhesive force of the bonding adhesive layer can be controlled accurately.

In some implementations, the first temperature T1 satisfies: 22° C.≤T1≤28° C. and the second temperature T2 satisfies: 60° C.≤T2≤90° C. Controlling the first temperature T1 near the room temperature can help facilitate the reaching of the first temperature T1. The difference between the second temperature T2 and the first temperature T1 can ensure change magnitude of the adhesive force.

In some implementations, the first adhesive force F1 and the second adhesive force F2 satisfies: 2:1≤F1:F2≤4:1. The difference between the first adhesive force F1 and the second adhesive force F2 can help form a preset difference in retention force on the LEDs.

In some implementations, the first adhesive force F1 is greater than or equals 0.6 MPa, to ensure effective retention of the first adhesive force F1 on the LEDs.

This disclosure also provides a mass transfer method, for LED transfer by using the adapter plate as described above, which includes the following.

Multiple LEDs are disposed on a first substrate. The adapter plate is connected with the first substrate in the environment at the second temperature T2, to make the bonding adhesive layer attach to at least a portion of the multiple LEDs. The adapter plate is cooled to the environment at the first temperature T1 and the LEDs attached to the adapter plate are transferred for connecting with a second substrate, to make the LEDs attach to the second substrate. The adapter plate is heated to the environment at the second temperature T2 and the LEDs are transferred to the second substrate.

In the mass transfer method of this disclosure, the adapter plate is adopted to transfer the LEDs. Therefore, during transfer of the LEDs, the difference in retention force can be produced by the change in the adhesive force of the adapter plate at different temperatures, to ensure smooth transfer of the LEDs.

In some implementations, the first substrate is a growth substrate. The multiple LEDs are disposed on the first substrate as follows. The multiple LEDs are grown on the growth substrate.

When the first substrate is the growth substrate, the adapter plate can be implemented as a temporary substrate, to transfer the LEDs.

In some implementations, the adapter plate is cooled to the environment at the first temperature T1 and the LEDs attached to the adapter plate are transferred for connecting with the second substrate, to make the LEDs attach to the second substrate, which includes the following.

The adapter plate is cooled to the environment at the first temperature T1. Temporary bonding is performed between the adapter plate and the growth substrate, where pressure of the temporary bonding is less than or equals 5 kg/f. The LEDs attached to the adapter plate are transferred for connecting with the second substrate.

When the adapter plate is implemented as the temporary substrate, the temporary bonding needs to be performed between the adapter plate and the growth substrate to provide retention on the LEDs.

In some implementations, after performing temporary bonding between the adapter plate and the growth substrate, all of the multiple LEDs are peeled off from the growth substrate through laser.

The multiple LEDs can be effectively peeled off from the growth substrate through laser.

In some implementations, after the LEDs are transferred to the second substrate, the LEDs are equipped, through the second substrate, on a display back plate of the Micro-LED display.

At this point, the second substrate can be implemented as a transfer substrate.

In some implementations, the second substrate is a display back plate of the Micro-LED display. The multiple LEDs are disposed on the first substrate as follows. All of the multiple LEDs that are grown on a growth substrate, are transferred to the first substrate.

When the second substrate is the display back plate, the adapter plate can be implemented as the transfer substrate.

In some implementations, the adapter plate is connected with the first substrate in the environment at the second temperature T2 to make the bonding adhesive layer attach to at least the portion of the multiple LEDs, which includes the following. The adapter plate is connected with the first substrate in the environment at the second temperature T2 to make the bonding adhesive layer attach to the portion of the multiple LEDs. The LEDs attached to the adapter plate are transferred for connecting with the second substrate, to make the LEDs attach to the second substrate, which includes the following. The LEDs attached to the adapter plate are transferred for connecting with the display back plate, to make the LEDs attach to driving electrodes on the display back plate corresponding to the LEDs.

When the adapter plate is implemented as the transfer substrate, only the portion of the multiple LEDs on the first substrate can be transferred to the display back plate at one time.

In some implementations, the adapter plate is heated to the environment at the second temperature T2 and the LEDs are transferred to the second substrate, which includes the following. The adapter plate is heated to the environment at the second temperature T2, by welding together the LEDs and the driving electrodes. The adapter plate is removed to transfer the LEDs to the display back plate.

Since the LEDs need to be equipped on the display back plate through welding, the adapter plate can be heated through heat of welding with no need to be heated separately.

Finally, this disclosure also provides a Micro-LED display, which includes a display back plate and multiple LEDs fixed on the display back plate. The multiple LEDs are fixed on the display back plate by adopting the mass transfer method described above.

In this disclosure, the bonding adhesive layer of the adapter plate can exhibit, through related settings, two different magnitude of adhesive force according to temperature changes in the transfer process of the LEDs. In the relatively high-temperature environment at the second temperature T2, pores in the bonding adhesive layer expand upon heating. Smaller contact area between the bonding adhesive layer and the LEDs, smaller adhesive force is. In the relatively low-temperature environment at the first temperature T1, the pores shrink upon cooling. Air pressure in the pores decreases and a negative pressure chamber is formed herein. The adhesive force on the LEDs thus increases. Therefore, when the adapter plate needs to retain the LEDs, the adapter plate is supposed to be in the environment at the first temperature T1. When the retention force on the LEDs provided by the adapter plate needs to be reduced, the adapter plate is supposed to be in the environment at the second temperature T2. As such, the difference in retention force on the LEDs can be generated to ensure smooth transfer of the LEDs.

For the Micro-LED display of this disclosure, due to employment of the mass transfer method as described above, the transfer process of the LEDs becomes smoother. The LEDs will also be avoided from damage due to too much retention force exerted. Therefore, production yield of the Micro-LED display can be improved.

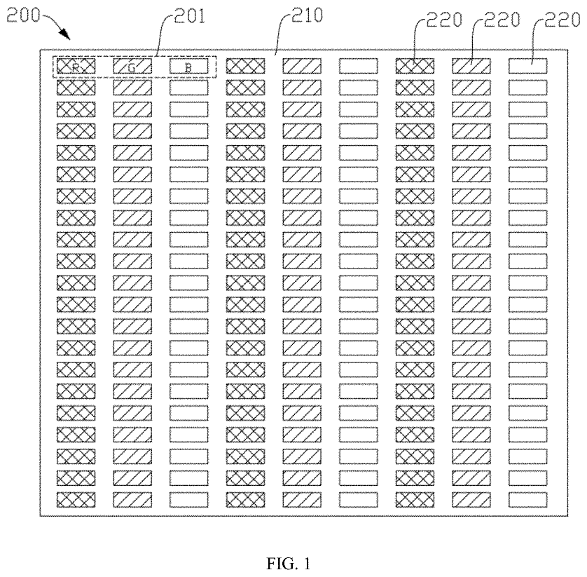

With reference to FIG. 1, this disclosure relates to a Micro-LED display 200, which includes a display back plate 210 and multiple LEDs 220 fixed on the display back plate 210. The multiple LEDs 220 are usually grouped in groups of three to form a pixel combining unit 201. The three LEDs 220 in the pixel combining unit 201 are “R, G, B” three-primary-color LEDs 220 respectively and are arranged sequentially in the pixel combining unit 201. Each of the multiple LEDs 220 can be seen as a sub-pixel unit in the pixel combining unit 201. The three LEDs 220 can emit light separately through control of a driving circuit on the display back plate 210. Subsequently, the colors are mixed to make the pixel combining unit 201 emit preset color light. Multiple pixel combining units 201 are arranged in array on the display back plate 210. In this way, display effect of color pictures of the Micro-LED display 200 can be realized correspondingly.

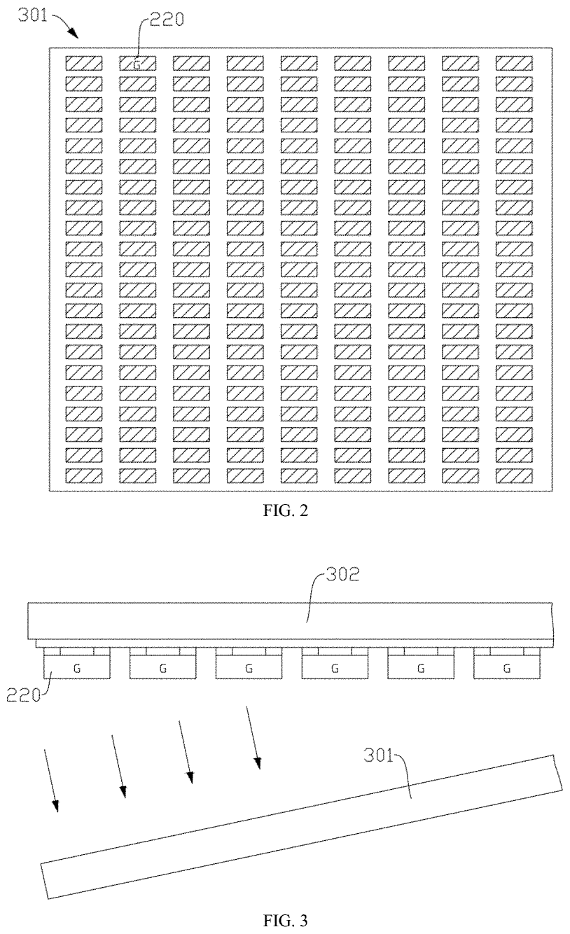

Further, as illustrated in FIG. 1, it requires three different growth substrates 301 to grow the “R, G, B” three-primary-color LEDs 220 in the pixel combining unit 201. With reference to FIG. 2, each growth substrate 301 can only be used to grow the LEDs 220 of the same color and the multiple LEDs 220 on one same growth substrate 301 are arranged in array.

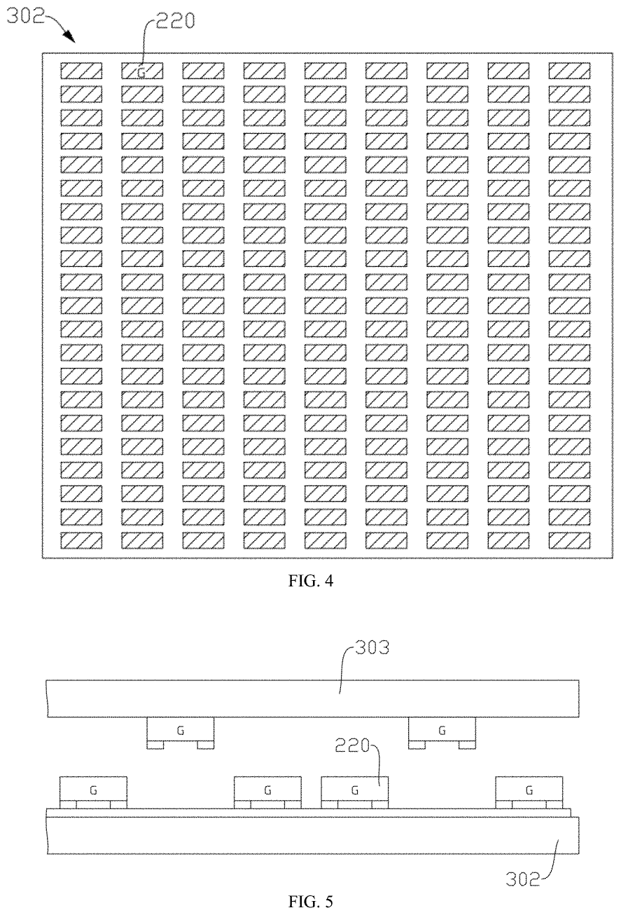

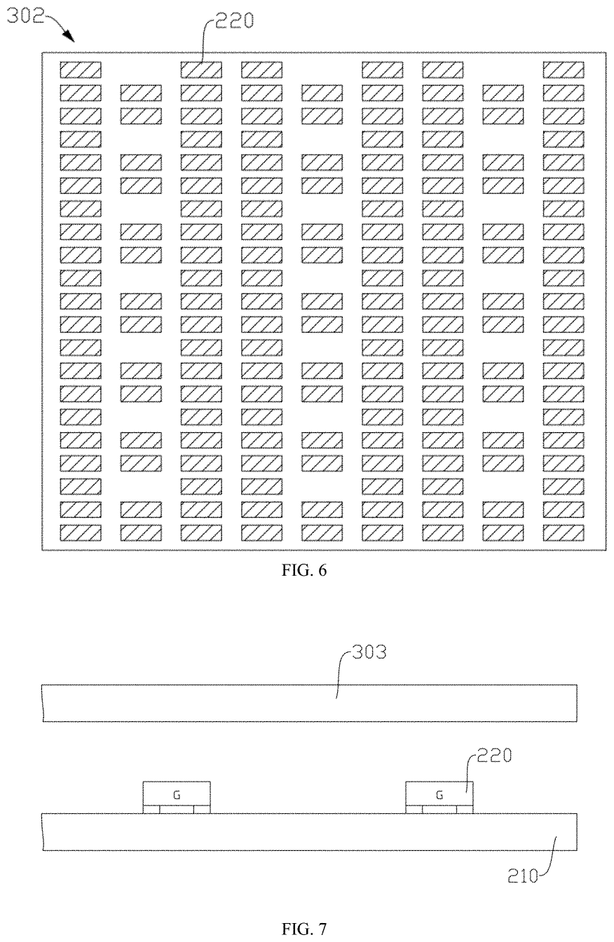

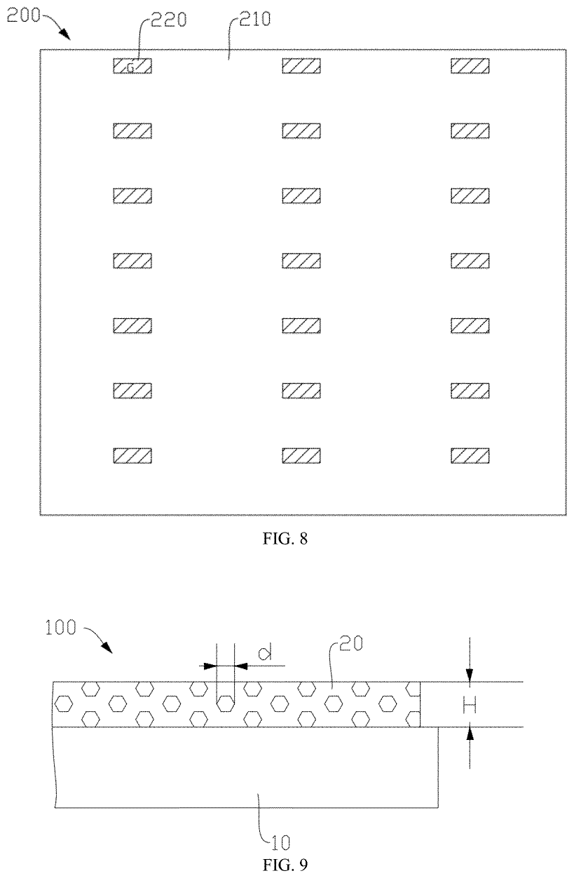

With reference to FIG. 3 and FIG. 4, a temporary substrate 302 is needed to remove all of the grown LEDs 220 from the growth substrate 301. As illustrated in FIG. 5 and FIG. 6, a portion of the LEDs 220 are removed from the temporary substrate 302 through a transfer substrate 303, according to arrangement of the same-colored LEDs 220 required by the Micro-LED display 200. The removed LEDs 220 are aligned and equipped on the display back plate 210 (with reference to FIG. 7 and FIG. 8). It should be understood that after the LEDs 220 of different colors are transferred, through the transfer substrate 303, to the display back plate 210, the mass transfer process of the Micro-LED display 200 is completed.

In the operations as described above, the LEDs 220 needs to be transferred to the temporary substrate 302 from the growth substrate 301 before the LEDs 220 are transferred to the transfer substrate 303 from the temporary substrate 302. At last, the LEDs 220 are transferred to the display back plate 210 from the transfer substrate 303. In other words, when the LEDs 220 are placed on the temporary substrate 302 and the transfer substrate 303, the LEDs 220 need to retain on the temporary substrate 302/the transfer substrate 303 and then separate from the temporary substrate 302/the transfer substrate 303.

With reference to an adapter plate 100 provided in this disclosure illustrated in FIG. 9, the adapter plate is used to realize the mass transfer of the LEDs 200 in the process of manufacturing the Micro-LED display 200. The adapter plate includes a substrate 10 and a bonding adhesive layer 20 laminated on the substrate 10. The bonding adhesive layer 20 is used to bind and transfer the LEDs 220. The bonding adhesive layer is made of organic silicone or acrylic acid. A thickness H of the bonding adhesive layer satisfies: 10 um≤H≤25 um, for example, 15 um≤H≤20 um. Further, porosity P of the bonding adhesive layer of the adapter plate 100 satisfies: 20%≤P≤40%, for example, 30%. In this way, the bonding adhesive layer has a first adhesive force F1 in an environment at a first temperature T1 and has a second adhesive force F2 in an environment at a second temperature T2 higher than the first temperature T1. Meanwhile, the first adhesive force F1 is greater than the second adhesive force F2.

It should be understood that, through setting of the material, thickness and porosity of the bonding adhesive layer 20, the bonding adhesive layer 20 has the function of presenting different adhesive forces at different temperatures. When the bonding adhesive layer 20 adheres to the LEDs 220, the adapter plate 100 in this disclosure can form different retention forces on the LEDs 220 in the environments at different temperatures. In other words, through controlling the temperature of the bonding adhesive layer 20 of the adapter plate 100 in this disclosure, the difference in retention force on the LEDs 220 can be formed within the adapter plate 100.

When the adapter plate 100 is applied in the mass transfer process of the LEDs 220 of the Micro-LED display 200, the adapter plate 100 can be implemented as the temporary substrate 302 or the transfer substrate 303. When it is needed to transfer the LEDs 220 to the adapter plate 100, the environment temperature of the adapter plate 100 can be lowered to increase the retention force of the adapter plate 100 on the LEDs 220. In this way, it can be ensured that, with the relatively large retention force of the adapter plate 100, the LEDs 220 are transferred smoothly to the adapter plate 100. When it is needed to remove the LEDs 220 from the adapter plate 100, the environment temperature of the adapter plate 100 can be increased to reduce the retention force of the adapter plate 100 on the LEDs 220. In this way, it can be ensured that, with the relatively small retention force of the adapter plate 100, the LEDs 220 are removed smoothly from the adapter plate 100.

Therefore, in the whole mass transfer process of the LEDs 220, the retention force on the LEDs 220 in each transfer process need not to be increased step by step. Instead, since the adapter plate 100 has an adjustable adhesive force, the differences in retention force can be formed in the two transfer processes, thereby reducing the demand for retention force in each transfer process of the LEDs 220. In this way, the LEDs 220 can also be transferred smoothly. The adapter plate 100 in this disclosure can help avoid the LEDs 220 from too much retention force exerted in each mass transfer process, to protect the LEDs 220 or the display back plate 210 from damage.

In some implementations, the bonding adhesive layer 20 is made of polydimethylsiloxane (PDMS). In an example, dimethylbenzene is added into liquid polydimethylsiloxane to form a prepolymer. The dimethylbenzene can dilute the polydimethylsiloxane and increase the fluidity level of the polydimethylsiloxane to avoid too much bubbles in the prepolymer. In some implementations, a ratio of the dimethylbenzene to the polydimethylsiloxane is in a range of 2:1˜4:1, for example, 3:1. Subsequently, glucose, sucrose, and sodium chloride particles are added into the prepolymer with high fluidity level. The prepolymer is then mixed and stirred homogeneously. The substrate 10 can be made of quartz glass or sapphire. The prepolymer mixed with the particles above is prepared on the substrate 10 through spin coating and so on, and then solidified. A thickness of coating can refer to the thickness H of the bonding adhesive layer 20. The infiltrated glucose, sucrose, and sodium chloride particles are then removed through water bath. The excessive dimethylbenzene is also removed synchronously. In the end, a porous resin material made of polydimethylsiloxane can be obtained, that is, the bonding adhesive layer 20 in this disclosure.

The glucose, sucrose, and sodium chloride particles in the prepolymer can be used to produce pores. Because the bubbles in the prepolymer are reduced due to the employment of the dimethylbenzene, the pores in the solidified bonding adhesive layer 20 are mainly produced by the particles. After removing the particles through water bath, the positions in the bonding adhesive layer 20 where space of the particles used to locate turn into the pores. In other words, through controlling the size of the glucose, sucrose, and sodium chloride particles, the size of the pores in the bonding adhesive layer 20 can also be controlled. In some implementations, the bonding adhesive layer 20 has an aperture d satisfying: 50 nm≤d≤1000 nm, for example, 20 nm≤d≤600 nm. The adhesive force of the bonding adhesive layer 20 can be controlled accurately within the range of the aperture d.

In some implementations, the first temperature T1 is set to satisfy: 22° C.≤T1≤28° C., for example, 25° C. At this point, the first temperature T1 belongs to room temperature, which makes it easier to control the environment temperature of the bonding adhesive layer 20. Waste of energy can also be avoided. The second temperature T2 satisfies: 60° C.≤T2≤90° C., for example, 70° C.≤T2≤80° C. When the second temperature T2 is 30° C. or more higher than the first temperature T1, an apparent difference in adhesive force can be formed under the two temperature environments.

In some implementations, the first adhesive force F1 and the second adhesive force F2 satisfies: 2:1≤F1:F2≤4:1, for example, F1:F2=3:1. The difference between the first adhesive force F1 and the second adhesive force F2 can help form a preset difference in retention force on the LEDs 220.

In some implementations, the first adhesive force F1 is set to be greater than or equals 0.6 MPa. Therefore, the second adhesive force ranges from 0.15 MPa˜0.3 MPa. In order to ensure that the LEDs 220 can be retained effectively with the first adhesive force F1, sufficient retention force needs to be provided by the adapter plate 100.

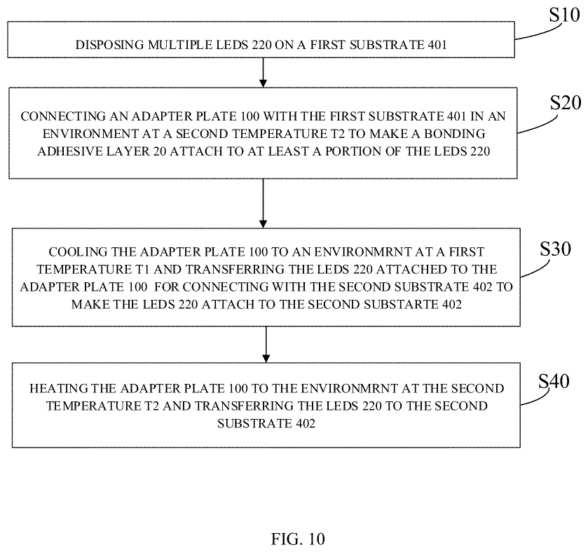

With reference to FIG. 10, a mass transfer method is provided in this disclosure. The method begins at S10. At S10, multiple LEDs 220 are disposed on a first substrate.

At S20, an adapter plate 100 is connected with the first substrate in an environment at a second temperature T2, to make a bonding adhesive layer 20 attach to at least a portion of the LEDs 220. The mass transfer method in this disclosure is realized accompanied with the adapter plate 100. The adapter plate 100 is used to transfer the LEDs 220 on the first substrate to a second substrate. The adapter plate 100 has an adhesive force varying with the temperature. Therefore, when the adapter plate 100 connects with the first substrate and removes the LEDs 220 from the first substrate, the adapter plate 100 can be put in the temperature at the second temperature T2. At this point, the bonding adhesive layer 20 of the adapter plate 100 attaches to a portion of or the entire LEDs 220 on the first substrate. Pores on the surface of the bonding adhesive layer 20 touch the LEDs 220 and sealed spaces are formed. Gas density within the bonding adhesive layer 20 is relatively small and pore volume is relatively big, because the second temperature T2 is relatively high.

At S30, the adapter plate 100 is cooled to an environment at a first temperature T1, the LEDs 220 attached to the adapter plate 100 are transferred for connecting with the second substrate, to make the LEDs 220 attach to the second substrate. When the adapter plate 100 is cooled to the first temperature T1, gases within the bonding adhesive layer 20 contracts and larger retention force is formed on the LEDs 220. Accompanied with the retention force, formed by hydrogen bond of the polydimethylsiloxane or Van der Waals force, on the LEDs 220, a first adhesive force F1 can be provided by the adapter plate 100 on the LEDs 220. Therefore, the retention force between the adapter plate 100 and the LEDs 220 is different from the retention force between the first substrate and the LEDs 220, which makes it easier to remove LEDs 220 from the first substrate. The adapter plate 100 will transfer the LEDs 220 to the second substrate for connecting.

At S40, the adapter plate 100 is heated to the environment at the second temperature T2 and the LEDs 220 are transferred to the second substrate. After the LEDs 220 connect with the second substrate, the adapter plate 100 is heated again to the environment at the second temperature T2 to separate the adapter plate 100 from the LEDs 220. The retention force on the LEDs 220 is thus reduced to form the second adhesive force F2. At this point, the retention force of the adapter plate 100 on the LEDs 220 reduces, and thus the retention force between the adapter plate 100 and the LEDs 220 is different from that between the second substrate and the LEDs 220, which makes it easier to remove the LEDs 220 from the adapter plate 100.

In the mass transfer method in this disclosure, when the adapter plate 100 is used to transfer the LEDs 220 to the second substrate from the first substrate, the temperature of the adapter plate 100 is adjusted to change its retention force on the LEDs 220, which realizes the smooth transfer of the LEDs 220.

It should be noted that, in the mass transfer method, when it comes to adjusting the temperature of the adapter plate 100, it can be indirectly achieved through changing the environment temperature, or directly achieved through controlling the temperature of the adapter plate 100 itself. Since a substrate 10 is usually made of heat-conductive material, the temperature control for the bonding adhesive layer 20 can be achieved through direct connection with a heat source or a refrigerant and the substrate 10, which makes power consumption relatively small.

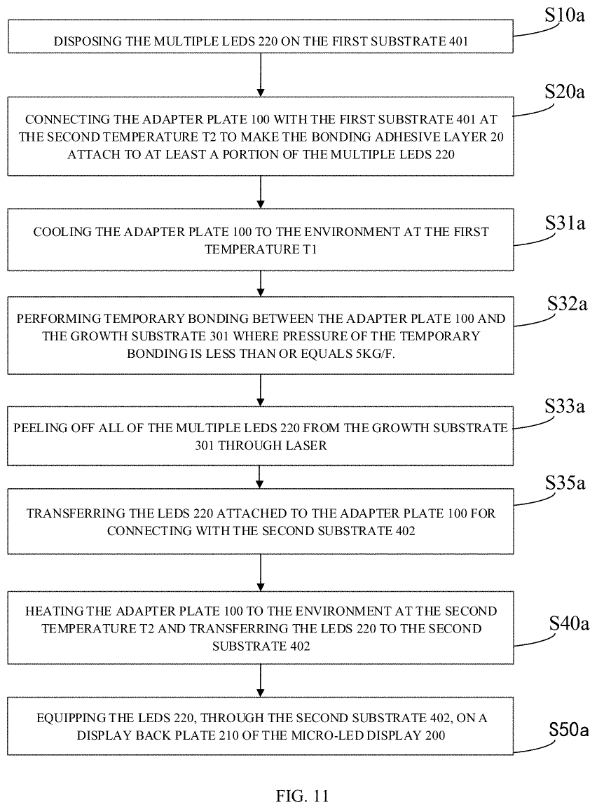

As already described in the implementations above, in the mass transfer process, the adapter plate 100 can be implemented as the temporary substrate 302 or the transfer substrate 303. With reference to FIG. 11, the mass transfer method of this disclosure provides an implementation where, when the adapter plate 100 is implemented as the temporary substrate 302, S10: “the multiple LEDs 220 are disposed on the first substrate” can be described as follows. At S10a, the multiple LEDs 220 are grown on the growth substrate.

Since the adapter plate 100 is implemented as the temporary substrate 302, it is natural that: the first substrate be implemented as growth substrate 301 and the second substrate the transfer substrate 303. Therefore, the operation that the multiple LEDs 220 are disposed on the first substrate which is implemented as the growth substrate 301 is described as that: the multiple LEDs 220 are grown on the growth substrate 301.

With further reference to FIG. 11, in some implementations, the adapter plate 100 is implemented as the temporary substrate 302. For example, at S30, “the adapter plate 100 is cooled to the environment at the first temperature T1, and the LEDs 220 attached to the adapter plate 100 are transferred for connecting with the second substrate, to make the LEDs 220 attach to the second substrate,” which includes the following operations.

At S31a, the adapter plate 100 is cooled to the environment at the first temperature T1.

At S32a, temporary bonding is performed between the adapter plate 100 and the growth substrate, where pressure of the temporary bonding is less than or equals 5 kg/f.

At S35a, the LEDs 220 attached to the adapter plate 100 are transferred for connecting with the second substrate.

Since the LEDs 220 are grown on the growth substrate 301, the temporary bonding is usually performed between the adapter plate 100 implemented as the temporary substrate 302 and the growth substrate 301, to ensure effective retention of the adapter plate 100 on the LEDs 220. Meanwhile, in order to protect the LEDs 220, the pressure of the temporary bonding is less than or equals 5 kg/f. Thereafter, the LEDs 220 attached to the adapter plate 100 are peeled off from the growth substrate 301. It should be noted that usually the temporary substrate 302 will peel off all of the multiple LEDs 220 from the growth substrate 301.

In some implementations, at S32a, after “temporary bonding is performed between the adapter plate 100 and the growth substrate 301”, the method further includes the following.

At S33a, all of the multiple LEDs 220 are peeled off from the growth substrate 301 through laser.

The LEDs 220 can be effectively peeled off from the growth substrate 301 through laser, to further ensure that the LEDs 220 are effectively transferred to the adapter plate 100.

In some implementations, at S40a, after “the LEDs 220 are transferred to the second substrate”, the method further includes the following.

At S50a, the LEDs 220 are equipped, through the second substrate, on a display back plate 210 of a Micro-LED display 200.

Since the second substrate is implemented as the transfer substrate 303, in the following operations in the implementation, the LEDs 220 need to be gradually transferred, through the second substrate implemented as the transfer substrate 303, to the display back plate 210 for assembly, to form the Micro-LED display 200.

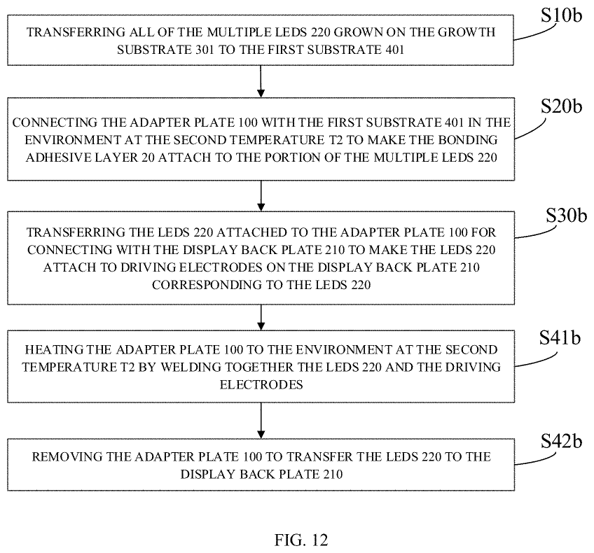

With reference to FIG. 12, the adapter plate 100 can also be implemented as the transfer substrate 303. At this point, the second substrate is the display back plate 210 of the Micro-LED display 200 and the first substrate is implemented as the temporary substrate 302. As illustrated in FIG. 12, at S10, “the multiple LEDs 220 are disposed on the first substrate”, which includes the following.

At S10b, all of the multiple LEDs 220 grown on the growth substrate 301 are transferred to the first substrate.

In other words, at this point, the first substrate is implemented as the temporary substrate 302. The multiple LEDs 220 are disposed on the first substrate as follows. The multiple LEDs 220 are transferred from the growth substrate 301 to the first substrate.

In some implementations, with further reference to FIG. 12, at S20, “the adapter plate 100 is connected with the first substrate in the environment at the second temperature T2 to make the bonding adhesive layer 20 attach to at least the portion of the multiple LEDs 220”, which includes the following.

At S20b, the adapter plate 100 is connected with the first substrate in the environment at the second temperature T2 to make the bonding adhesive layer 20 attach to the portion of the multiple LEDs 220.

Subsequently, at S30, “the LEDs 220 attached to the adapter plate 100 are transferred for connecting with the second substrate, to make the LEDs 220 attach to the second substrate”, which further includes the following.

At S30b, the LEDs 220 attached to the adapter plate 100 are transferred for connecting with the display back plate 210, to make the LEDs 220 attach to driving electrodes on the display back plate 210 corresponding to the LEDs 220.

When the adapter plate 100 is implemented as the transfer substrate 303, the LEDs 220 are transferred by the adapter plate 100 to the display back plate 210. At this point, actually, the portion of the LEDs 220 are removed from the first substrate (i.e., temporary substrate 302), through the adapter plate 100, according to arrangement of the same-colored LEDs 220 required by the Micro-LED display 200. The removed LEDs 220 are aligned and equipped on the display back plate 210 to make the portion of the LEDs 220 attach to the driving electrodes on the display back plate 210. In other words, when the adapter plate 100 is implemented as the transfer substrate 303, the LEDs 220 removed from the temporary substrate 302 by the adapter plate 100 are the portion of the LEDs 220 with corresponding arrangement on the display back plate 210. The portion of the LEDs 220 are aligned and equipped on the display back plate 210 according to preset positions to attach to the driving electrodes on the display back plate 210.

In some implementations, at S40b, “the adapter plate 100 is heated to the environment at the second temperature T2 and the LEDs 220 are transferred to the second substrate”, which includes the following.

At S41b, the adapter plate 100 is heated to the environment at the second temperature T2, by welding together the LEDs 220 and the driving electrodes.

At S42b, the adapter plate 100 is removed to transfer the LEDs 220 to the display back plate 210.

In the implementation, after the LEDs 220 are aligned with and attached to the corresponding driving electrodes, the LEDs 220 and the driving electrodes need to be welded together, to realize the equipment of the LEDs 220 on the display back plate 210. Since heat will be generated in welding process, in the implementations where the adapter plate 100 is implemented as the transfer substrate 303, there is no need to separately heat the adapter plate 100 after the LEDs 220 are aligned with and attached to the display back plate 210 through the adapter plate 100. The adapter plate 100 can be heated by welding heat to reach the environment at the second temperature T2. In this way, the retention force of the adapter plate 100 on the LEDs 220 can be reduced to facilitate separation of the LEDs 220 from the adapter plate 100.

This disclosure provides a Micro-LED display 200, which includes a display back plate 210 and multiple LEDs 220 fixed on the display back plate 210, where the multiple LEDs 220 are fixed on the display back plate 210 by adopting the mass transfer method as described above. It should be understood that, due to employment of the mass transfer method as described above, the transfer process of the LEDs 220 becomes smoother. The LEDs 220 will also be avoided from damage due to too much retention force exerted. Therefore, production yield of the Micro-LED display 200 can be improved.

The implementations are described. It should be noted that any modifications, or improvements that can be made by those skilled in the art without departing from the spirits and principles of this disclosure shall all be encompassed within the protection of this disclosure.

What is claimed is:

1. An adapter plate, used in a manufacturing process of a Micro-LED (light-emitting diode) display to realize a mass transfer of LEDs, the adapter plate comprising:
a substrate; and
a bonding adhesive layer laminated on the substrate and used to bind and transfer the LEDs, wherein the bonding adhesive layer is made of organic silicone or acrylic acid, has a thickness H satisfying: 10 um≤H≤25 um, and has porosity P satisfying: 20%≤P≤40%, to make the bonding adhesive layer have a first adhesive force F1 in an environment at a first temperature T1 and have a second adhesive force F2 in an environment at a second temperature T2 higher than the first temperature T1, wherein the first adhesive force F1 is greater than the second adhesive force F2.

2. The adapter plate of claim 1, wherein the bonding adhesive layer is made of polydimethylsiloxane diluted with dimethylbenzene and a ratio of the dimethylbenzene to the polydimethylsiloxane is in a range of 2:1˜4:1.

3. The adapter plate of claim 1, wherein the bonding adhesive layer has an aperture d satisfying: 50 nm≤d≤1000 nm.

4. The adapter plate of claim 1, wherein the first temperature T1 satisfies: 22° C.≤T1≤28° C. and the second temperature T2 satisfies: 60° C.≤T2≤90° C.

5. The adapter plate of claim 4, wherein the first adhesive force F1 and the second adhesive force F2 satisfies: 2:1≤F1:F2≤4:1.

6. The adapter plate of claim 5, wherein the first adhesive force F1 is greater than or equals 0.6 MPa.

7. A mass transfer method, for LED transfer by using an adapter plate, the adapter plate comprising a substrate and a bonding adhesive layer laminated on the substrate and used to bind and transfer LEDs, wherein the bonding adhesive layer is made of organic silicone or acrylic acid, has a thickness H satisfying: 10 um≤H≤25 um, and has porosity P satisfying: 20%≤P≤40%, to make the bonding adhesive layer have a first adhesive force F1 in an environment at a first temperature T1 and have a second adhesive force F2 in an environment at a second temperature T2 higher than the first temperature T1, wherein the first adhesive force F1 is greater than the second adhesive force F2; the method comprising:
disposing a plurality of LEDs on a first substrate;
connecting the adapter plate with the first substrate in the environment at the second temperature T2 to make the bonding adhesive layer attach to at least a portion of the plurality of LEDs;
cooling the adapter plate to the environment at the first temperature T1 and transferring the LEDs attached to the adapter plate for connecting with a second substrate, to make the LEDs attach to the second substrate; and
heating the adapter plate to the environment at the second temperature T2 and transferring the LEDs to the second substrate.

8. The mass transfer method of claim 7, wherein the first substrate is a growth substrate and disposing the plurality of LEDs on the first substrate comprises:
growing the plurality of LEDs on the growth substrate.

9. The mass transfer method of claim 8, wherein cooling the adapter plate to the environment at the first temperature T1 and transferring the LEDs attached to the adapter plate for connecting with the second substrate, to make the LEDs attach to the second substrate comprises:
cooling the adapter plate to the environment at the first temperature T1;
performing temporary bonding between the adapter plate and the growth substrate, wherein pressure of the temporary bonding is less than or equals 5 kg/f; and
transferring the LEDs attached to the adapter plate for connecting with the second substrate.

10. The mass transfer method of claim 9, further comprising:
after performing temporary bonding between the adapter plate and the growth substrate;
peeling off all of the plurality of LEDs from the growth substrate through laser.

11. The mass transfer method of claim 7, further comprising:
after transferring the LEDs to the second substrate,
equipping the LEDs, through the second substrate, on a display back plate of the Micro-LED display.

12. The mass transfer method of claim 7, wherein the second substrate is a display back plate of the Micro-LED display and disposing the plurality of LEDs on the first substrate comprises:
transferring all of the plurality of LEDs growing on a growth substrate to the first substrate.

13. The mass transfer method of claim 12, wherein
connecting the adapter plate with the first substrate in the environment at the second temperature T2 to make the bonding adhesive layer attach to at least the portion of the plurality of LEDs comprises:
connecting the adapter plate with the first substrate in the environment at the second temperature T2 to make the bonding adhesive layer attach to the portion of the plurality of LEDs; and
transferring the LEDs attached to the adapter plate for connecting with the second substrate, to make the LEDs attach to the second substrate comprises:
transferring the LEDs attached to the adapter plate for connecting with the display back plate, to make the LEDs attach to driving electrodes on the display back plate corresponding to the LEDs.

14. The mass transfer method of claim 13, wherein heating the adapter plate to the environment at the second temperature T2 and transferring the LEDs to the second substrate comprises:
heating the adapter plate to the environment at the second temperature T2, by welding together the LEDs and the driving electrodes; and
removing the adapter plate to transfer the LEDs to the display back plate.

15. A Micro-LED (light-emitting diode) display, comprising a display back plate and a plurality of LEDs fixed on the display back plate, wherein the plurality of LEDs are fixed on the display back plate by adopting a mass transfer method comprising:
disposing the plurality of LEDs on a first substrate;
connecting the adapter plate with the first substrate in the environment at the second temperature T2 to make the bonding adhesive layer attach to at least a portion of the plurality of LEDs;
cooling the adapter plate to the environment at the first temperature T1 and transferring the LEDs attached to the adapter plate for connecting with a second substrate, to make the LEDs attach to the second substrate; and
heating the adapter plate to the environment at the second temperature T2 and transferring the LEDs to the second substrate.

16. The Micro-LED display of claim 15, wherein the first substrate is a growth substrate and disposing the plurality of LEDs on the first substrate comprises:
growing the plurality of LEDs on the growth substrate.

17. The Micro-LED display of claim 16, wherein cooling the adapter plate to the environment at the first temperature T1 and transferring the LEDs attached to the adapter plate for connecting with the second substrate, to make the LEDs attach to the second substrate comprises:
cooling the adapter plate to the environment at the first temperature T1;
performing temporary bonding between the adapter plate and the growth substrate, wherein pressure of the temporary bonding is less than or equals 5 kg/f, and
transferring the LEDs attached to the adapter plate for connecting with the second substrate.

18. The Micro-LED display of claim 17, further comprising:
after performing temporary bonding between the adapter plate and the growth substrate;
peeling off all of the plurality of LEDs from the growth substrate through laser.

19. The Micro-LED display of claim 15, further comprising:
after transferring the LEDs to the second substrate,
equipping the LEDs, through the second substrate, on the display back plate of the Micro-LED display.

20. The Micro-LED display of claim 15, wherein the second substrate is the display back plate of the Micro-LED display and disposing the plurality of LEDs on the first substrate comprises:
transferring all of the plurality of LEDs growing on a growth substrate to the first substrate.
